(19) United States
(12) Patent Application Publication
(10) Pub. No.: US 2006/0237741 A1
(43) Pub. Date: Oct. 26, 2006

(54) Light-emitting diode and method for production thereof

(75) Inventors: Ryouichi Takeuchi, Saitama (JP); Wataru Nabekura, Saitama (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K

(21) Appl. No.: 10/548,534

(22) PCT Filed: Mar. 9, 2004
(86) PCT No.: PCT/JP04/03039

§ 371 Date: May 9, 2006

Related U.S. Application Data
(60) Provisional application No. 60/455,586, filed on Mar. 19, 2003.
(60) Provisional application No. 60/530,229, filed on Dec. 18, 2003.

(30) Foreign Application Priority Data
Mar. 13, 2003 (JP) 2003-067428
May 12, 2003 (JP) 2003-408246

(51) Int. Cl. H01L 33/00

(52) U.S. Cl. 257/103; 257/E33.013

(57) ABSTRACT

An LED (10) includes a compound semiconductor layer (13) that contains a light-emitting part and an alkali glass substrate (150) that contains at least 1 mass % of one element selected from sodium, calcium, barium and potassium and is transparent to light-emitting wavelength of the part. The substrate is fixed or joined in contact with the semiconductor layer. In a method for producing the diode (10), the semiconductor layer (13) is grown on a semiconductor substrate (1) untransparent to the wavelength, the grown semiconductor layer and alkali glass substrate are joined by the anode junction method, the untransparent substrate is removed, a first ohmic electrode (15) having a first polarity is formed on part of a main surface of the semiconductor layer, a second ohmic electrode (16) is formed on the semiconductor layer having a second polarity, and the first ohmic electrode and semiconductor layer are covered with a metal reflecting layer (14).

### CROSS REFERENCE TO RELATED APPLICATIONS

This application is an application filed under 35 U.S.C. §111(a) claiming the benefit pursuant to 35 U.S.C. §119(e)(1) of the filing dates of Provisional Application Ser. No. 60/455,586 filed Mar. 19, 2003 and Provisional Application Ser. No. 60/530,229 filed Dec. 18, 2003 pursuant to 35 U.S.C. §111(b).

### TECHNICAL FIELD

This invention relates to a light-emitting diode using the technique of applying an alkali glass substrate and particularly to a light-emitting diode of high luminance and a method for the production thereof.

### BACKGROUND ART

Heretofore, the technique of removing an opaque semiconductor substrate and attaching a transparent substrate by adhesion for the purpose of imparting increased luminance and exalted mechanical strength to a light-emitting diode has been known. In the light-emitting diode manufactured by means of this technique, a transparent substrate is joined by adhesion to the surface of a semiconductor layer or to the surface exposed by the removal of an opaque semiconductor substrate. The method for joining this transparent substrate by adhesion is known in various forms including a method of directly joining by adhesion a transparent substrate to a semiconductor layer at an elevated temperature under pressure as disclosed in JP-C 3230638, a method of directly utilizing the wafer bonding technique as disclosed in JP-A HEI 6-302857, and a method of utilizing a transparent viscous substance, such as an epoxy resin, as disclosed in JP-A 2002-246640. Further, a method of joining a semiconductor layer and a transparent substrate through a transparent electroconductive film, such as ITO, has been proposed as disclosed in JP-C 2588849.

The prior art has found technical difficulty in the means to join the whole surface of a semiconductor to a transparent substrate and, therefore, has devised a rich variety of methods for the joining. The method of direct junction generally necessitates a high temperature of 700° C. or more and a high pressure, exerts a large stress on the semiconductor layer, and frequently induces an uneven and defective junction unless the surface is flat and smooth. The junction at an elevated temperature gives rise to a warp due to a difference in coefficients of thermal expansion, induces such a large mechanical stress as to sustain a rupture during the course of cooling and, consequently, more often than not open a crack as well, incites a degradation of the quality of the light-emitting part, and calls for highly advanced technique and equipment for ensuring stable production.

Meanwhile, as a means to join a semiconductor and a transparent substrate, a method of utilizing a resinous adhesive layer with the object of coping with a semiconductor having a defective surface condition has been devised. While this method is capable of mending the stress at an elevated temperature and the defective junction due to a coarse surface, it encounters the problem of exposing the step of heat treatment subsequent to the junction to a heavy restriction because the resinous material cannot withstand high temperatures. The formation of an ohmic electrode, for example, entails a heat treatment at a temperature of 400° C. or more. The resinous material, therefore, incurs problems, such as deterioration of quality, occurrence of separation and loss of transparency.

Further, owing to the stress mentioned above and the deterioration of the adhesive layer, the joined part frequently sustains separation and crack during such steps as dicing and scribing for the separation of a diode. Thus, it has been difficult to establish a method of junction that reconciles perfect adhesion at a low temperature and a low stress and satisfaction of resistance to heat.

The conventional method of joining the entire surface of a semiconductor to a transparent substrate has entailed a degradation of the quality of a light-emitting part and necessitated highly advanced technique and equipment to ensure stable production. It has been further difficult to establish a method of junction that reconciles perfect adhesion at a low temperature and a low stress and satisfaction of resistance to heat.

This invention has been proposed in the light of the problems mentioned above. It was initiated in the discovery of an adhesive layer exhibiting high adhesive strength and excelling in resistance to heat even under the condition of junction using a temperature of 500° C. or less. It is, therefore, aimed at providing a light-emitting diode of high luminance allaying the stress generated during the course of junction and ensuring stable production and a method for the production thereof.

In the semiconductor light-emitting diode contemplated by this invention, the impartation of high luminance is accomplished because the removal of the opaque substrate and the attachment of the transparent substrate result in eliminating the absorption of light in the semiconductor substrate and further because the provision of the compound semiconductor layer on part of the surface thereof with an ohmic electrode and a metal reflecting layer results in enabling the light of the light-emitting part to be efficiently extracted to the exterior. Specifically, this invention provides the following means.

The present inventors have discovered that the technique of anode junction can be utilized for joining a compound semiconductor layer and a transparent substrate using glass and further that the compound semiconductor layer and an alkali glass substrate can be stably joined under a low stress and consequently that the product enjoying high resistance to heat can be obtained.

### DISCLOSURE OF THE INVENTION

The present invention provides a light-emitting diode comprising a compound semiconductor layer that contains a light-emitting part and an alkali glass substrate that contains at least 1 mass % of one element selected from the group consisting of sodium (Na), calcium (Ca), barium (Ba) and potassium (K), and exhibits transparency to light-emitting wavelength of the light-emitting part, the alkali glass substrate having a construction fixed or joined in contact with the compound semiconductor layer.

In the light-emitting diode, the one element of the alkali glass substrate has a concentration A in a neighborhood of a junction with the semiconductor layer that is lower than a concentration B on a back surface of the alkali glass substrate and satisfies relation of B>1.5×A.

In the light-emitting diode, the alkali glass substrate has silicon dioxide (SiO₂) and boron oxide (B₂O₃) as main components thereof and has a lead content of 0.1 mass % or less.

In the light-emitting diode, a joint surface between the alkali glass substrate and the compound semiconductor layer is a mirror-processed surface having an average surface roughness of 2 nm or less.

In the light-emitting diode, the alkali glass substrate has a coefficient of thermal expansion in a range of 3 to 7×10⁻⁶/K.

In the light-emitting diode, the alkali glass substrate has a thickness of 70 μm or more and 300 μm or less, and the compound semiconductor layer has a thickness of 30 μm or less.

In the light-emitting diode, the light-emitting part contained in the compound semiconductor layer is formed of AlGaInP with high emission efficiency.

In the light-emitting diode, the compound semiconductor layer contains a layer of GaP that is a material suitable for etching stoppage and current diffusion.

In the light-emitting diode, the compound semiconductor layer and the alkali glass substrate each have an As content of 0.1 mass % or less.

The present invention also provides a method for the production of a light-emitting diode, comprising a step of growing a compound semiconductor layer on a semiconductor substrate untransparent to light-emitting wavelength to form a grown compound semiconductor layer, a step of joining the grown compound semiconductor layer and an alkali glass substrate transparent to the light-emitting wavelength by an anode junction method, a step of removing the untransparent semiconductor substrate, a step of forming a first ohmic electrode having a first polarity on part of a main surface opposite an anode junction surface of the compound semiconductor layer, a step of forming a second ohmic electrode on a compound semiconductor layer having a second polarity in the grown semiconductor layer and a step of covering the first ohmic electrode and a compound semiconductor layer having the first polarity in the grown semiconductor layer with a metal reflecting layer.

In the method for the production of a light-emitting diode, the semiconductor substrate untransparent to light-emitting wavelength has grown thereon a compound semiconductor layer that contains a light-emitting part having a light-emitting layer, and the compound semiconductor layer is polished before the step of joining, thereby bringing an average surface roughness to 2 nm or less.

In the method for the production of a light-emitting diode, the metal reflecting layer is formed of gold (Au) or rhodium (Rh) that is high in reflectance and stable in material.

In the method for the production of a light-emitting diode, the untransparent semiconductor substrate has a temperature in a range of 300 to 500° C. during the anode junction method.

In the method for the production of a light-emitting diode, the step of removing the untransparent semiconductor substrate includes a step of removing part of the compound semiconductor layer, and the step of removing part of the compound semiconductor layer includes a step of performing selective etching treatment for etching only crystals of a predetermined composition.

The method for the production of a light-emitting diode can further comprise a step of covering the light-emitting layer with a protective film.

The present invention further provides a light-omitting diode lamp having an electrode of a light-emitting diode chip produced by the method for the production of a light-emitting diode and constructed in a flip chip electrode by joining it with a gold (Au) bump.

In the light-emitting diode lamp, the electrode of the light-emitting diode chip is constructed in a flip chip electrode by joining it with a soldering alloy having a low melting point of 450° C. or less.

The above and other objects, features and advantages of the present invention will become apparent to those skilled in the art from the description made herein below with reference to the accompanying drawings.

### BRIEF DESCRIPTION OF THE DRAWINGS

FIG. 1 is a plan view of a semiconductor light-emitting diode covered by Examples 1 and 2 of this invention.

FIG. 2 is a cross section taken through FIG. 1 along line II-II.

FIG. 3 is a cross section of an epitaxial wafer covered by Examples 1 and 2 of this invention and Comparative Examples 1 to 6.

FIG. 4 is a plan view of a semiconductor light-emitting diode covered by Comparative Example 7.

FIG. 5 is a cross section taken through FIG. 4 along line V-V.

FIG. 6 is a plan view of a light-emitting diode covered by Examples 1 and 2 of this invention and Comparative Examples 1 to 6.

FIG. 7 is a cross section of a light-emitting diode covered by Examples 1 and 2 of this invention and Comparative Examples 1 to 6.

FIG. 8 is a plan view of a modified example of the structure of FIG. 1, having the electrode of the n-type region disposed as being separated by an equal distance from the electrode of the p-type region.

FIG. 9 is a plan view of a modified example of the structure of FIG. 1, forming the p-electrode in the shape of a mesh so as to uniformize the potential applied to the n-electrode.

FIG. 10 is a plan view of a modified example of the structure of FIG. 1, thinning the part of a small distance between the electrodes in order to offset the area and the distance and ensure uniform flow of electric current.

FIG. 11 is a plan view of a modified example of the structure of FIG. 1, using parallel electrodes in order to ensure uniform flow of electric current.

FIG. 12 is a plan view of an example of forming a bilaterally or vertically symmetrical shape in order to uniformize the flow of electric current.

FIG. 13 is a plan view of a modified example of the structure of FIG. 1, forming the p-electrode in the shape of an array of stepping-stones in order to ensure uniform flow of electric current.

### BEST MODE FOR CARRYING OUT THE INVENTION

The transparent glass substrate that is used for the anode junction is a so-called alkali glass substrate having boron oxide and silicon oxide as main components and containing sodium oxide, calcium oxide, barium oxide and potassium oxide. This invention sets the concentration of sodium (Na), calcium (Ca), barium (Ba) or potassium (K) element in the alkali glass at a level of 1 mass % or more. The upper limit of the concentration of the element is 30 mass %, preferably 15 mass % or less, and more preferably 10 mass % or less. If the concentration of the element exceeds 30 mass %, the excess will possibly result in degrading the joining strength or inducing alkali pollution. From the viewpoint of the load on the environment, the material for the alkali glass is preferred to avoid containing lead and arsenic. The alkali glass substrate is preferred to have a coefficient of thermal expansion approximating that of a compound semiconductor layer, i.e. the level in the range of 3 to 7×10⁻⁶/K. The reason for this approximation is that if the difference in the coefficient of thermal expansion is unduly large, it will prevent the stress on the semiconductor layer during the course of heating and cooling from decreasing.

The thickness of the alkali glass substrate is preferred to be 300 μm or less on account of the ease with which the fabrication into a chip is accomplished. The thickness is preferred to be 70 μm or more in the light of the occurrence of a crack during the adhesion of a transparent substrate and the convenience of handling a die bond as during the step of assembly using a chip. Further, the content of lead in the alkali glass substrate is preferred to be 0.1 mass % or less, favorably 0.01 mass % or less, and more preferably in the range 0.01 mass % to 0.0001 mass %.

As the opaque semiconductor substrate for basing the growth of a compound semiconductor layer, substrates of GaAs, InP, GaP and Si are available. The light-emitting part may be formed of a GaP, an AlGaInP mixed crystal or a GaAlAs mixed crystal, for example. Such other semiconductors as are utilized in the known compound semiconductor light-emitting diodes are also available. For the light-emitting part, structures, such as the single hetero structure, double hetero structure and quantum well structure that are generally used for a light-emitting part, are available. The light-emitting diode of the structure contemplated by this invention has a great effect particularly in enhancing the luminance of a light-emitting diode provided with an AlGaInP light-emitting part using a GaAs substrate which is difficult to allow addition to the wall thickness and opaque in the ordinary structure on account of the lattice matching.

In obtaining a light-emitting part of high luminance, it is the ordinary rule common to the field to select the material of a light-emitting part having a matching lattice constant and to induce it to grow a compound semiconductor layer. As the method for this growth, known techniques, such as the method of liquid phase growth, the MBE method and the MOCVD method, are available. In terms of mass productivity and quality, however, the MOCVD method proves most favorable. In the compound semiconductor layer, known techniques, such as the buffer layer heretofore used to cope with a semiconductor substrate, the Bragg reflection layer, the etching stop layer intended for selective etching, the contact layer for lowering the contact resistance of an ohmic electrode, the electric current diffusion layer, the electric current stopping layer for controlling the region for allowing flow of electric current and the electric current constriction layer, may be used as combined in addition to the light-emitting part. These layers may be properly selected and combined to suit factors, such as the method of production, the cost and the quality.

In superposing the alkali glass substrate and the semiconductor substrate and performing the anode junction on the resultant laminate, a commercially available apparatus for anode junction may be utilized. This method consists in applying an electric field to the glass substrate and the compound semiconductor layer while keeping the laminate heated. Further, during the course of the junction, it is preferable to apply to the laminate a pressure of a degree that prevents the joined surfaces from slipping. This pressure possibly enhances the uniformity and the strength of junction. Though the junction prefers use of a low temperature, the temperature actually proper for the junction falls in the range of 300 to 500° C., especially optimally in the neighborhood of 400° C.

The opaque semiconductor substrate can be removed by methods, such as mechanical work, abrasion and chemical etching, for example. Among other conceivable chemical etching techniques, the selective etching which utilizes the difference of etching speed depending on the quality of a material proves to be the optimum method in terms of mass-productivity, reproducibility and uniformity. This selective etching is a method which, when used where an AlGaInP layer is superposed on a GaAs substrate, for example, selectively etches the GaAs layer exclusively.

A flip chip light-emitting diode structure is optimally obtained by forming the surface for drawing light of a transparent substrate, removing a first electrode and part of a compound semiconductor layer on the surface of the compound semiconductor layer on the side on which an opaque substrate has been removed, forming a second electrode on a second polar compound semiconductor layer, and further disposing a metal reflecting layer for covering the first electrode and the surface of the compound semiconductor layer.

As another method for the production of a diode, any of the known techniques for the production of a light-emitting diode may be utilized. Specifically, the light-emitting diode is produced via the steps of forming an ohmic electrode, forming a protective film, and separating, testing and rating a chip.

Examples of the manufacture of a semiconductor light-emitting diode contemplated by this invention will be described specifically with reference to the accompanying drawings. It is plain that this invention is not restricted to the Examples.

### EXAMPLE 1

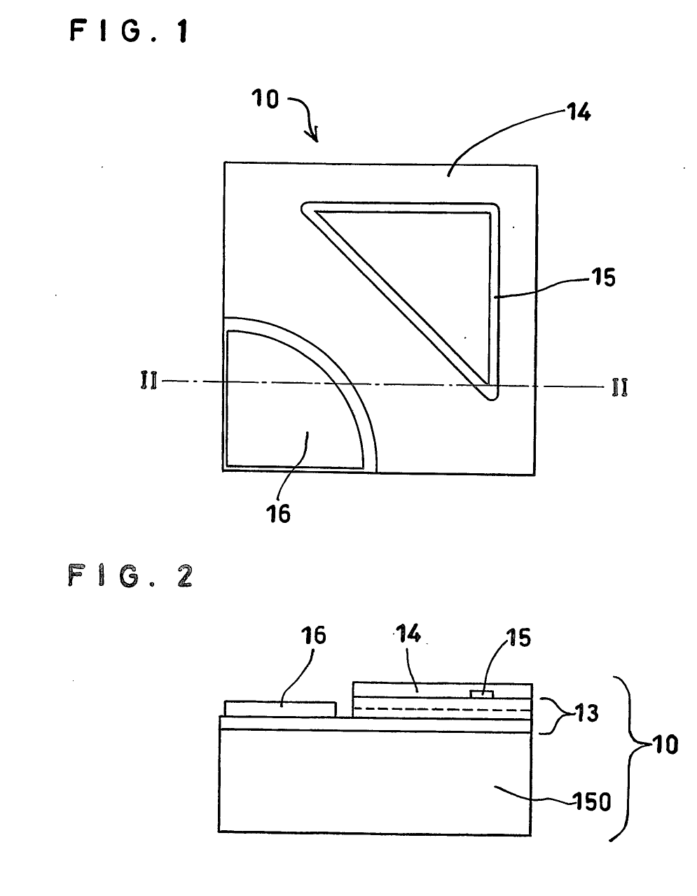

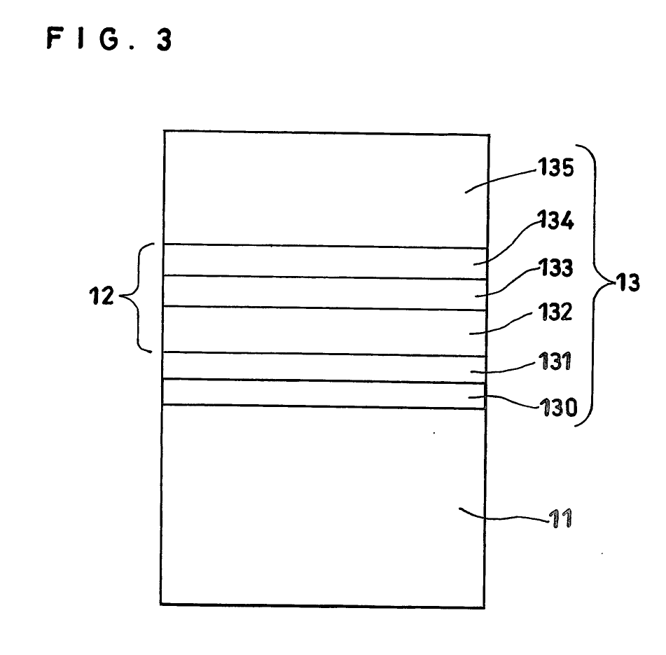

FIG. 1 and FIG. 2 illustrate a manufactured semiconductor light-emitting diode, FIG. 1 depicting a plan view thereof and FIG. 2 a cross section taken through FIG. 1 along line II-II. FIG. 3 is a detailed plan view of the laminar structure of a semiconductor epitaxial wafer used in a semiconductor light-emitting diode. The manufactured semiconductor light-emitting diode is a red light-emitting diode (LED) having AlGaInP for a light-emitting layer.

In this LED, as illustrated in FIG. 3 depicting a cross-sectional structure thereof, a compound semiconductor layer 13 formed by sequentially superposing a buffer layer 130 made of Si-doped n-type GaAs, an etching stop layer 131 made of Si-doped n-type (Al_{0.5}Ga_{0.5})_{0.5}In_{0.5}P, a lower cladding layer 132 made of Si-doped n-type (Al_{0.7}Ga_{0.8})_{0.5}In_{0.5}P, a light-emitting layer 133 made of undoped (Al_{0.2}Ga_{0.8})_{0.5}In_{0.5}P, an upper cladding layer 134 made of Zn-doped p-type (Al_{0.7}Ga_{0.8})_{0.5}In_{0.5}P and a Zn-doped p-type GaP layer 135 is formed on a semiconductor substrate 11 made of GaAs single crystal having a plane inclined by 2° from a Si-doped n-type (001) plane. A light emission layer 12 of this LED has a double hetero structure that is formed of the lower cladding layer 132, the light-emitting layer 133 and the upper clad layer 134.

In this Example, first by the low-pressure metal organic chemical vapor deposition method (MOCVD method) using trimethyl aluminum ((CH₃)₃Al), trimethyl gallium ((CH₃)₃Ga) and trimethyl indium ((CH₃)₃In) as the raw materials for the component elements of Group III, the relevant compound semiconductor layers 130 to 135 were individually superposed on the semiconductor substrate 11 to form an epitaxial wafer. Diethylzinc ((C₂H₅)₂Zn) was used as the raw material for the doping of Zn. Disilane (Si₂H₆) was used as the raw material for the doping of Si. As the raw material for the component elements of Group V, phosphine (PH₃) or arsine (AsH₃) was used. The superposing temperatures of the component layers superposed by the MOCVD method in forming the compound semiconductor layer 13 were unified at 730° C. The carrier concentration of the GaAs buffer layer 130 was about 5×10¹⁸ cm⁻¹³ and the wall thickness thereof was about 0.2 μm. The (Al_{0.5}Ga_{0.5})_{0.5}In_{0.5}P carrier concentration of the etching stop layer 131 was about 2×10¹⁸ cm⁻³ and the wall thickness thereof was about 1 μm. The carrier concentration of the lower cladding layer 132 was about 8×10¹⁷ cm⁻³ and the wall thickness thereof was about 1 μm. The light-emitting layer 133 had an undoped wall thickness of 0.5 μm. The carrier concentration of the upper cladding layer 134 was about 2×10¹⁷ cm⁻³ and the wall thickness thereof was about 1 μm. The carrier concentration of the GaP layer 135 was about 5×10¹⁸ cm⁻³ and the wall thickness thereof was 7 μm.

Next, the surface of the epitaxially grown compound semiconductor layer was polished to an average surface roughness of 0.5 nm. This roughness could be rated by visually observing the cross section of the layer by the use of an optical surface roughness meter, an atomic force microscope or an electron microscope. As a transparent substrate 150, a so-called Pyrex® glass (coefficient of thermal expansion: 5×10⁻⁶/K) using B₂O₃ and SiO₂ as main components thereof and having a thickness of 150 μm was used. Of course, the surface of this glass was mirror-polished to an average roughness of 1 nm.

Subsequently, the compound semiconductor layer and the transparent substrate were set as superposed on an anode junction device. The interior of this device was evacuated to vacuum. The semiconductor layer and the transparent substrate were nipped between upper and lower heaters and heated to 400° C. Further, an electric voltage of +800 V was applied to the surface of the transparent substrate to join the two layers directly. The time at this joining process was set at 15 minutes. The total concentration of the elements, Na, Ca, K and Ba, on the joined surface of the glass substrate after the junction was about 3 mass % in the neighborhood of the joined surface and about 6 mass % on the back surface. Consequently, the alkali concentration on the back surface was about twice that on the joined surface.

Then, the opaque GaAs substrate 11 and the GaAs buffer layer 130 were selectively removed by the use of a known ammonia-based etchant. On the surface of the etching stop layer 131, a first ohmic electrode 15 was formed through vacuum-depositing an AuGe alloy till a thickness of 0.3 μm. This electrode was given the work of patterning by using a common photolithographic means to give rise to the linear n-type ohmic electrode 15 of a triangular shape having a line width of about 8 μm.

On the entire surface of the compound semiconductor layer 13 including the surface of the electrode 15, a metal reflecting layer 14 made of gold (Au) in a thickness of 1.5 μm was formed by the technique of vacuum deposition. Optionally, rhodium (Rh) may be used in the place of the gold.

The compound semiconductor layer 13 was subjected first to the work of patterning and then to the work of selective etching with a bromine-based etchant till the GaP layer 135, i.e. an electric current dispersion layer, was exposed in the fan-shaped region 150 μM in radius to allow the formation of the second electrode.

For the purpose of forming a second ohmic electrode 16, a pattern was formed on the surface of the GaP layer 135 in a fan-shaped region measuring 130 μm in radius. First, the resist surface of the pattern was clad with a gold-beryllium alloy film having a thickness of 0.5 μm and a gold film having a thickness of 1 μm by an ordinary technique of vacuum evaporation in popular use. Subsequently, the resist was removed by the known liftoff technique to give rise to a fan-shaped second electrode 16.

After the first and second electrodes had been formed, the compound semiconductor layer was subjected to an alloying heat treatment in a current of nitrogen at 450° C. for 10 minutes to form a low-resistance ohmic contact between the first and second electrodes and the compound semiconductor layer.

A semiconductor light-emitting diode 10 was obtained by forming the first electrode 15 furnished with the metal reflecting layer 14 and the second electrode 16 as described above, removing by etching the compound semiconductor layer in the region destined to be cut into chips and consequently exposing the glass surface, and cutting what remained into pieces of the shape of a diode by the ordinary scribing technique. The semiconductor light-emitting diode 10, as viewed in a plan view illustrated in FIG. 1, is the square having a side of 300 μm and a thickness of about 160 μm.

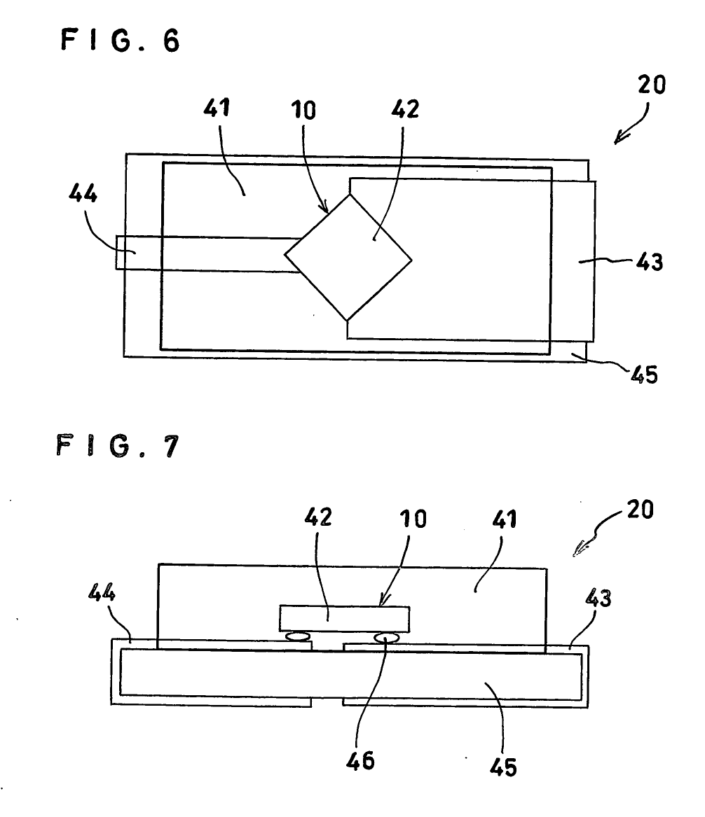

A light-emitting diode lamp 20 of the flip chip structure assembled using the semiconductor light-emitting diode 10 will be described below with reference to the plan view of FIG. 6 and the cross-sectional view of FIG. 7. A ball bump 46 of gold was formed on a first electrode terminal 44 and a second electrode terminal 43 which were formed on a substrate 45, and the second electrode 16 and the metal reflecting layer 14 of the light-emitting diode 10 were brought into contact with the gold bump 46 and connected thereto by contact bonding. Then, the joint consequently formed was sealed with a transparent epoxy resin 41 to complete manufacture of the light-emitting diode (LED) lamp 20.

When an electric current was passed in a forward direction to the first electrode terminal 44 and the second electrode terminal 43 of the LED lamp manufactured as described above, the radiated light was reflected on the metal reflecting layer 14 and advanced via the first surface and the lateral face of the transparent GaAs layer 135 to induce emission of a red color having a main wavelength of about 620 nm. The forward-direction voltage (V_{f}: per 20 mA) resulting from the flow of an electric current of 20 mA in the forward direction was about 2.0 V, a magnitude reflecting the good ohmic properties of the electrodes 15 and 16. The intensity of light emission at this time was 180 mcd, a high magnitude reflecting the fact that the light-emitting part had a high emission-efficiency and the efficiency of drawing the emission to the exterior was properly contrived.

Though the preceding Example was described as manufacturing an LED lamp by the use of an n-type semiconductor substrate, an LED lamp manufactured using a p-type semiconductor substrate acquires the effect of this invention.

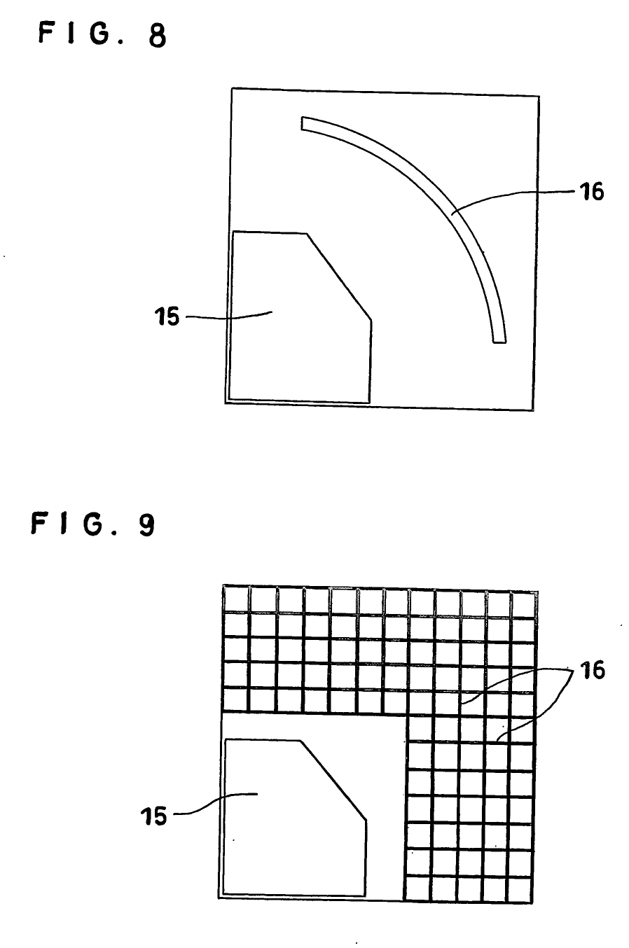

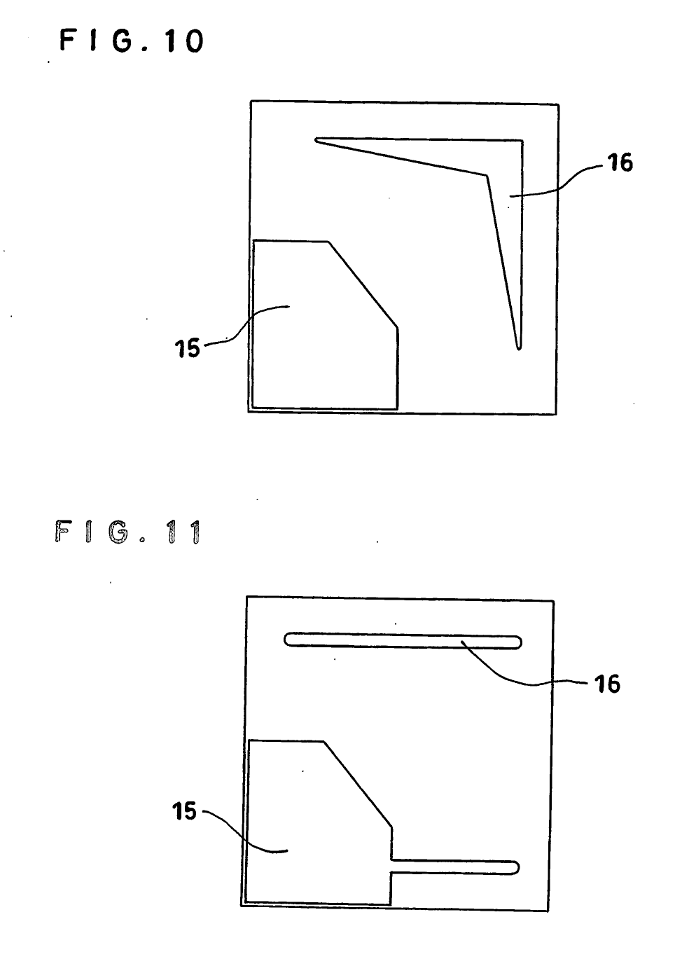

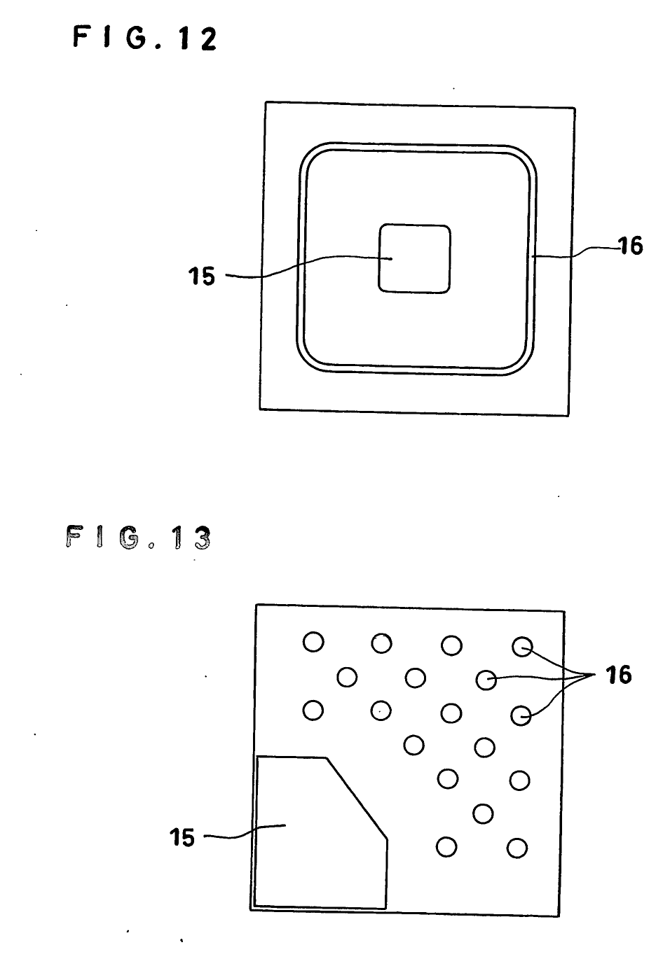

Further, though the light-emitting part mentioned above was described as using a double hetero structure of AlGaInP, a light-emitting part utilizing a known technique, such as the MQW structure, acquires the effect of this invention. While the n-type ohmic electrode 15 was formed in a triangular shape in the preceding Example, it is commendable to form such a varying electrode pattern as illustrated in FIG. 8 through FIG. 13 to ensure uniform flow of electric current to the light-emitting part. Evidently, the chip may be formed in the shape of a triangle or a quadrangle, whichever fits the occasion better. The electrode pattern illustrated in FIG. 8 had the electrode 15 for the n-type region (hereinafter referred to as “n-electrode”) disposed as separated by an equal distance from the electrode 16 for the p-type region (hereinafter referred to as “p-electrode”) in order to allow uniform flow of electric current to the n-electrode. The electrode pattern illustrated in FIG. 9 had the p-electrode formed in the shape of a mesh in order to uniformize the potential exerted on the n-electrode. The electrode pattern illustrated in FIG. 10 had the part of a decreased distance between the electrodes thinned in order to offset the area and the distance and ensure uniform flow of electric current. The electrode pattern illustrated in FIG. 11 was intended to ensure uniform flow of electricity by using parallel electrodes. This shape formed a rectangular chip and manifested a prominent effect. The electrode pattern illustrated in FIG. 12 had a bilaterally or vertically symmetrical shape in order to uniformize the electric current. The electrode pattern illustrated in FIG. 13 had the p-electrode formed in the shape of an array of stepping-stones in order to uniformize the electric current. A structure obtained by covering the n-electrode 15 and the p-electrode 16 with a gold electrode and connecting the gold electrode to external electrodes is still capable of feeding an electric current.

While the preceding description depicted an ordinary LED in the shape of a chip, a display grade package of the shape of a so-called bombshell differing in cross section or a light-emitting diode differing in emission wavelength is still capable of acquiring the same effect.

### EXAMPLE 2

A junction was carried out by following the procedure of Example 1 while applying a pressure of 2 kg/cm² (19.8 N/cm²) during the junction of positive electrodes. The other component steps were the same as those of Example 1. As regards the characteristic properties of the light-emitting diode, the forward-direction voltage (V_{f}: per 20 mA) during the flow of an electric current of 20 mA in the forward direction was about 2.0 V. The intensity of light emission at this time was such as to produce a degree of luminance of 170 mcd.

### COMPARATIVE EXAMPLES

Comparative experiments were carried out through the procedures of Example 1 and Example 2 while changing the conditions of junction. The results of rating the comparative experiments are shown additionally in Table 1. In Comparative Examples 1 to 3, the junction was attempted by thermo-compression bonding instead of the anode junction. No junction was formed, however, between the semiconductor layer and the glass substrate.

TABLE 1

| | | | | | Coefficient | | | | |
|---|---|---|---|---|---|---|---|---|---|
| | | Temperature | | | of | | | | |
| | Method | of | Voltage | | thermal | Surface | | | |
| | of | junction | applied | Pressure | expansion | roughness | | | |
| | junction | (° C.) | (V) | (kg/cm²) | (10⁻⁶/K) | (nm) | Junction | Separation | Luminance |
| Ex. 1 | Anode | 400 | 800 | 0 | 5 | 0.5 | ◯ | ◯ | 180 |
| Ex. 2 | Anode | 400 | 800 | 2 | 4 | 0.5 | ◯ | ◯ | 170 |
| Comp. | Compression | 400 | 0 | 2 | 5 | 0.5 | X | — | — |
| Ex. 1 | | | | | | | | | |
| Comp. | Compression | 500 | 0 | 2 | 5 | 0.5 | X | — | — |
| Ex. 2 | | | | | | | | | |
| Comp. | Compression | 600 | 0 | 3 | 5 | 0.5 | X | — | — |
| Ex. 3 | | | | | | | | | |
| Comp. | Anode | 400 | 800 | 2 | 8 | 0.5 | Crack | — | — |
| Ex. 4 | | | | | | | | | |
| Comp. | Anode | 400 | 800 | 2 | 2 | 0.5 | Crack | — | — |
| Ex. 5 | | | | | | | | | |
| Comp. | Anode | 400 | 800 | 2 | 4 | 2 | ◯ | X | — |
| Ex. 6 | | | | | | | | | |
| Comp. | None | — | — | — | — | — | — | — | 60 |
| Ex. 7 | | | | | | | | | |

In Comparative Examples 4 and 5, the anode junction was carried out under conditions for largely varying the coefficient of thermal expansion of glass from that of a semiconductor layer. The samples sustained a crack during the course of the junction and failed to produce a diode. In Comparative Example 6, the junction was attempted under conditions allowing the semiconductor layer to have a high surface roughness. The sample sustained separation during the course of the removal of the substrate and failed to produce a light-emitting diode.

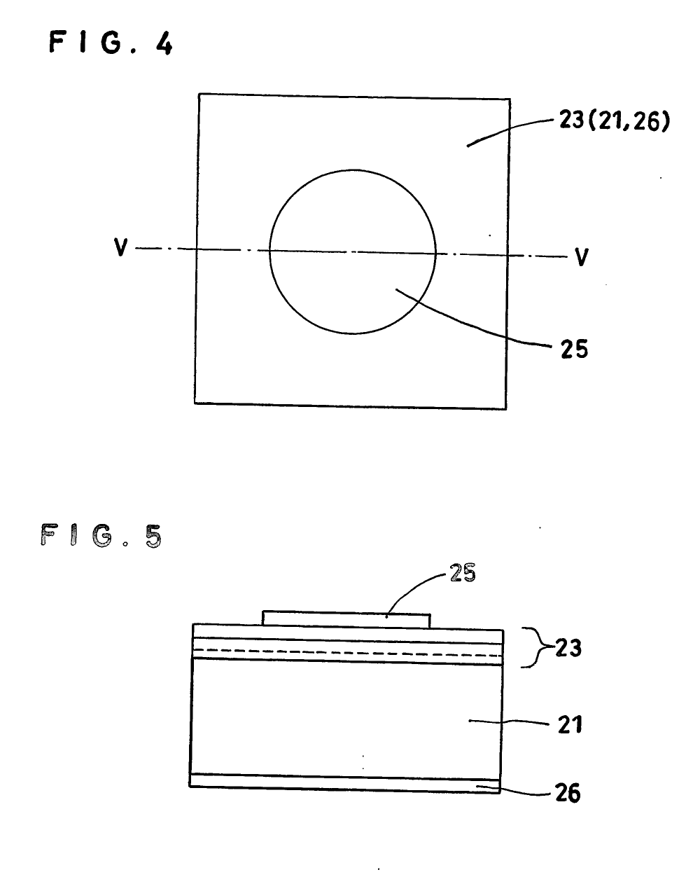

In Comparative Example 7, a semiconductor light-emitting diode of the square having a side of 300 μm was manufactured in an ordinary structure illustrated in FIG. 4 and FIG. 5 using the same epitaxial wafer as in Example 1 while omitting the removal of an opaque substrate and the junction of a glass substrate. FIG. 4 is a plan view of the semiconductor light-emitting diode manufactured in Comparative Example 7, and FIG. 5 is a cross section taken through FIG. 4 along line V-V. In FIG. 4 and FIG. 5, reference numeral 23 denotes a semiconductor layer, 25 a first ohmic electrode, and 26 a second ohmic electrode formed on the back surface of a GaAs semiconductor substrate 21.

In Comparative Example 5, the upper ohmic electrode 25 was joined by gold wire bonding. The first ohmic electrode 25 was formed in the shape of a circle 130 μm in diameter for the purpose of securing an area necessary for the junction. On the surface of the semiconductor layer 23, a p-type ohmic electrode made of a gold-beryllium alloy and intended as the first ohmic electrode 25 was formed in a thickness of 0.3 μm, and gold was deposited in a thickness of 1 μm by the technique of vacuum evaporation. The coated semiconductor layer 23 was subjected to the work of patterning to give rise to the first ohmic electrode 25 measuring 130 μm in diameter.

Subsequently, when an electric current was passed in the forward direction to the first electrode terminal and the second electrode terminal of a flip chip LED manufactured in the same manner as in the Examples, a red light having a wavelength of about 620 nm was projected via the first surface and the lateral face of the transparent GaP layer 135. The forward-direction voltage (V_{f}: per 20 mA) during the flow of an electric current of 20 mA in the forward direction was about 2.0 V, a magnitude equal to that of the Examples. The intensity of light emission at this time was 60 mcd. This magnitude is less than one half of the magnitude obtained in the Examples of this invention. This low magnitude may be logically explained by a postulate that the efficiency of drawing the light to the exterior was degraded by the absorption of the emitted light by the GaAs substrate.

### INDUSTRIAL APPLICABILITY

The semiconductor light-emitting diode of this invention accomplishes addition to luminance because the removal of the opaque substrate and the application of the transparent substrate result in eliminating the absorption of light by the semiconductor substrate and the provision of part of the surface of the compound semiconductor layer with an ohmic electrode and a metal reflecting layer results in enabling the light from the light-emitting part to be drawn out efficiently. It is plain that the present invention can be applied not only to the light-emitting diode in the infrared region and the visible light region but also to the light-emitting diode in the far infrared region and the near ultraviolet region.

Further, the adoption of the flip chip structure brings such effects as facilitating the assemblage of a lamp, shunning breakage of a wire and exalting the reliability.

Further, by righting the method for junction of glass and a compound semiconductor layer, it is made possible to materialize an inexpensive process that substantially avoids the occurrence of a crack or separation and secures high productivity.

1. A light-emitting diode comprising a compound semiconductor layer that contains a light-emitting part and an alkali glass substrate that contains at least 1 mass % of one element selected from the group consisting of sodium (Na), calcium (Ca), barium (Ba) and potassium (K), and exhibits transparency to light-emitting wavelength of the light-emitting part, the alkali glass substrate having a construction fixed or joined in contact with the compound semiconductor layer.

2. The light-emitting diode according to claim 1, wherein the one element of the alkali glass substrate has a concentration A in a neighborhood of a junction with the semiconductor layer that is lower than a concentration B on a back surface of the alkali glass substrate and satisfies relation of B>1.5×A.

3. The light-emitting diode according to claim 1, wherein the alkali glass substrate has silicon dioxide (SiO₂) and boron oxide (B₂O₃) as main components thereof and has a lead content of 0.1 mass % or less.

4. The light-emitting diode according to claim 1, wherein a joint surface between the alkali glass substrate and the compound semiconductor layer is a mirror-processed surface having an average surface roughness of 2 nm or less.

5. The light-emitting diode according to claim 1, wherein the alkali glass substrate has a coefficient of thermal expansion in a range of 3 to 7×10⁻⁶/K.

6. The light-emitting diode according to claim 1, wherein the alkali glass substrate has a thickness of 70 μm or more and 300 μm or less, and the compound semiconductor layer has a thickness of 30 μm or less.

7. The light-emitting diode according to claim 1, wherein the light-emitting part contained in the compound semiconductor layer is formed of AlGaInP with high emission efficiency.

8. The light-emitting diode according to claim 1, wherein the compound semiconductor layer contains a layer of GaP that is a material suitable for etching stoppage and current diffusion.

9. The light-emitting diode according to claim 1, wherein the compound semiconductor layer and the alkali glass substrate each have an As content of 0.1 mass % or less.

10. A method for the production of a light-emitting diode comprising a step of growing a compound semiconductor layer on a semiconductor substrate untransparent to light-emitting wavelength to form a grown compound semiconductor layer, a step of joining the grown compound semiconductor layer and an alkali glass substrate transparent to the light-emitting wavelength by an anode junction method, a step of removing the untransparent semiconductor substrate, a step of forming a first ohmic electrode having a first polarity on part of a main surface opposite an anode junction surface of the compound semiconductor layer, a step of forming a second ohmic electrode on a compound semiconductor layer having a second polarity in the grown semiconductor layer and a step of covering the first ohmic electrode and a compound semiconductor layer having the first polarity in the grown semiconductor layer with a metal reflecting layer.

11. The method for the production of a light-emitting diode according to claim 1, wherein the semiconductor substrate untransparent to the light-emitting wavelength has grown thereon a compound semiconductor layer that contains a light-emitting part having a light-emitting layer, and the compound semiconductor layer is polished before the step of joining, thereby bringing an average surface roughness to 2 nm or less.

12. The method for the production of a light-emitting diode according to claim 10, wherein the metal reflecting layer is formed of gold (Au) or rhodium (Rh) that is high in reflectance and stable in material.

13. The method for the production of a light-emitting diode according to claim 11, wherein the untransparent semiconductor substrate has a temperature in a range of 300 to 500° C. during the anode junction method.

14. The method for the production of a light-emitting diode according to claim 11, wherein the step of removing the untransparent semiconductor substrate includes a step of removing part of the compound semiconductor layer, and the step of removing part of the compound semiconductor layer includes a step of performing selective etching treatment for etching only crystals of a predetermined composition.

15. The method for the production of a light-emitting diode according to claim 11, further comprising a step of covering the light-emitting layer with a protective film.

16. A light-omitting diode lamp having an electrode of a light-emitting diode chip produced by the method for the production of a light-emitting diode and constructed in a flip chip electrode by joining it with a gold (Au) bump.

17. The light-emitting diode lamp according to claim 16, wherein the electrode of the light-emitting diode chip is constructed in a flip chip electrode by joining it with a soldering alloy having a low melting point of 450° C. or less.
